(19) United States
(12) Patent Application Publication
(10) Pub. No.: US 2004/0124545 A1
(43) Pub. Date: Jul. 1, 2004

(54) High density integrated circuits and the method of packaging the same

(76) Inventor: Daniel Wang, Markham (CA)

Correspondence Address: HOFFMANN & BARON, LLP, 6900 JERICHO TURNPIKE, SYOSSET, NY, 11791, US

(21) Appl. No.: 10/736,486

(22) Filed: Dec. 15, 2003

Related U.S. Application Data
(63) Continuation-in-part of application No. 10/057,448, filed on Jan. 25, 2002.
Application No. 10/057,448 is a continuation of application No. 08/761,365, filed on Dec. 9, 1996, now abandoned.

(51) Int. Cl. H01L 23/48

(52) U.S. Cl. 257/784; 257/693

(57) ABSTRACT

An integrated circuit package comprising a substrate having terminal pads arranged in at least one row along a perimeter of a surface of the substrate, vias connecting the terminal pads directly to connectors on an opposite side of the substrate, a semiconductor chip mounted on the substrate, inside the perimeter, the chip having bond pads located on a surface of the chip, and a plurality of insulated bond wires, each of the bond wires extending from a bond pad on the chip to a terminal pad on the substrate, the substrate being sized and shaped to provide a sufficient number of rows of terminal pads and associated vias so that horizontal traces through the substrate are not required.

### FIELD OF THE INVENTION

This invention relates generally to the electrical arts and in particular to integrated circuit packages characterised as comprising a microchip attached or mounted onto a substrate.

### BACKGROUND OF THE INVENTION

Semiconductor chip technology continues to advance, with ever smaller chips being made and mass produced. Even the smallest chips though need to be connected to other components to form a functioning overall system. Thus, even though small, the chips are typically packaged onto substrates to form integrated circuit (IC) devices which provide input and output (I/O) electrical pad connections.

IC devices provide a large variety of functions for electronic equipment such as computers, electrical controls, audio and video equipment and communication equipment. They serve as the key component in such equipment. Their application is ever increasing into all other equipment ranging from cameras, calculators to appliances widely used in all households. The pervading trend in the production of many equipment, particularly in electrical and electronic equipment is the relentless reduction of their physical size ever smaller, the ability to process increasingly larger amounts of information at faster speeds, and all at a lesser manufacturing cost. Due to the wide application of IC devices in such a wide variety of equipment, their packaging or assembly becomes a critical step in the manufacturing process of the equipment employing such devices. Thus, the semiconductor packaging industry is constrained by the current trend described succinctly as “faster, denser and cheaper”, namely, faster microchips must be provided in denser packages at lower costs than current packaging solutions. The common element of each packaging solution is that it must make some form of interconnection from the microchip in such IC devices. When the microchip is connected to a carrier substrate, this component is known as a module or semiconductor package. This process is described as semiconductor assembly and packaging.

In order to harness the power of the microchip for application purposes, each chip must be assembled into a semiconductor package using some form of fine attachment process to connect to the output terminals on its surface areas commonly referred to as bonding pads or in brief, bond pads. Three main processes are commonly employed in semiconductor packaging, namely, Tape Area Bonding (commonly referred to as TAB which is also known as Tape Carrier Package or TCP), Controlled Collapse Chip Connection or C4 (more commonly referred to as Flip Chip), and Wire Bonding. Wire bonding is the dominant interconnection process used, estimated at approximately 90-95% of all semiconductor packaging, with Flip Chip at about 5-10% and TAB at about 1%.

In TAB bonding of semiconductor packages, the bond pads are usually provided solely along the perimeter of the microchip; and the chip is mounted onto a flexible carrier with its bond pads connected to mating circuitry on the flexible carrier. Gold bumps typically act as the interconnection medium between the microchip bond pads and the circuitry on the flexible carrier.

In flip chip bonding of semiconductor packages, bumps of solder are directly attached to the microchip bond pads which are typically made of metallized aluminum with additional underbumped metallurgy and ranging in dimension in the order of 3 to 6 mils (50 to 150 microns) diameter on a spacing of typically 9 to 20 mils (225 to 500 microns) pitch, and it can be arranged in an area array which may be located at any selected locations of the microchip. In U.S. Pat. No. 5,490,040 to Gene J. Gaudenzi et al, it is shown a flip chip construction in which a microchip is provided with a plurality of bond pads in a plurality of selected areas. Solder balls are provided at these bond pads which are aligned with a configuration of terminal pads formed on a multilayered epoxy glass substrate. Such a multilayered composite construction provides an increased number of I/O connections; however, it is again currently complex in overall composite structure and is also costly to use producing currently poor yields relative to the high yields achieved by conventional methods of IC packaging.

Traditionally, wire bonding technology has been restricted to attaching bare conductive wire to the bond pads which are provided solely around the perimeter of the microchip, the number of bond pads is limited in order to maintain the required spacing between neighboring pads (commonly referred to as “pad pitch”) to avoid contact causing short circuiting problems. Heretofore, many attempts have been made to increase the number of I/O connections. In U.S. Pat. No. 5,444,303 to Jonathon Greenwood et al, bond pads having a triangular shape are provided over the perimeter of the microchip to increase the number of bond pads; however, the effective increase in the number of bond pads still falls far short of the increasing demand for higher performance, I/O dense ICs. Another method commonly employed to increase I/O density as shown in U.S. Pat. No. 5,468,999 to Paul T. Lin et al, is by forming the bond pads in two staggering rows around the perimeter of the microchip as illustrated in FIG. 2. Such method of packaging is limited by the physical size of the perimeter of the microchip, and is also more costly due to the increased precision required to produce at a substantial premium such fine pitched wire bonds. Also, the tight spacing or fine pitch between neighboring bonds makes engineering changes or rework of the packaging extremely difficult and in many cases almost impossible.

In wire bonding of semiconductor packages, fine bare conductive wires made of either gold or aluminum are welded directly onto the microchip bond pads to achieve such interconnections. The wires are then fanned out and attached to similar pads or leads usually spaced much greater then 10 mils (250 microns) apart on the connecting substrate or carrier module. Wire bonding is the most popular packaging method, because it provides a flexible method of interconnecting the microchip to the substrate for I/O redistribution (commonly known as “fan out”). Wire bonding can be visualized as being similar to a sewing machine stitching and spot welding a conductive thread from the semiconductor microchip to the larger carrier package. The fragile wires are then covered by an encapsulating compound, usually epoxy, to protect them from physical damage. The wire bonding process is carried out at a very microscopic level as it stitches onto typically 50 to 100 microns square bond pads on the microchip which are spaced apart only 50 to 100 microns by using wires of 0.8 to 1.2 mils in size which is finer than human hair. Bond pads cannot be placed closer together, because of current limitations in the wire and wire bonding equipment due to at least four reasons: firstly, short circuiting may occur when fine bare wires are stitched closely adjacent to one another; secondly, the short circuiting problem may be worsened by the epoxy wire encapsulation process due to “wire sweep” causing wires to touch as the flowing epoxy compound unintentionally changes the critical spacing requirement between adjacent wires; thirdly, wires cannot be made finer with existing wire making processes and because of metallurgical limitations; and fourthly, the welding tools, known as bonding head capillaries, through which the wire is threaded may contact adjacent wires after having bonded prior wires to the chip bond pads causing short circuiting and damage to the wires during assembly. Capillaries cannot be made too narrow otherwise their mechanical strength and structural integrity would be compromised thus impeding their effectiveness.

There are typically two metal compositions used for making bonding wires today. One is the use of 99.9% pure gold, the other is aluminum alloy consisting of mainly aluminum with 1% of silicon or with 2% of magnesium. It is partly the metallurgical properties of these two metal types (gold versus aluminum) that have influenced the development of basically two different methods of attaching fine bonding wire for microelectronic interconnection purposes. Gold wire is normally attached using thermocompression or thermosonic ball bonding whereas aluminum alloy wire is connected by using ultrasonic wedge bonding since currently available aluminum wire is not conducive to the ball bonding operation. In addition, ball bonding by far is the most cost effective and the most widely available packaging interconnection method today. Ball bonding with gold wire provides acceptable connections but the intermetallic compound formation problems of mating two dissimilar metals, namely gold of the gold wire and aluminum of the metallized aluminum bonding pads, can negatively affect bond reliability. Compared to ball bonding, the wedge bonding process is relatively slow and rather inflexible (only unidirectional bonds) and it does not lend itself to automation to achieve high volume and high I/O production capabilities. Ball bonders have typically double the throughput rate of Wedge bonders and Ball bonders are rather flexible due to their ability to produce omnidirectional bonds.

Copper wire is also gaining interest as a bonding wire for ball-bonding, due to the inherent compatibility with copper circuitry currently being implemented on the surface of high speed chips. However, the copper wire bonding process is still in its early stages of feasibility and has not reached commercial acceptance due to potential reliability and manufacturing issues, such as oxidation of the copper surface causing weak second bonds and improper ball formation.

To permit the large number of connections required to be made for modem microchips, the substrate is typically a multi-layer substrate with horizontal or lateral circuit tracings on a number of levels through the substrate. The tracings are typically interconnected between levels by electrically conductive vias or via holes. The tracings lead to external electrical contacts on the underside of the substrate, from which electrical connections are made to the broader circuit. Most commonly a lead frame having electrical contacts in the form of leads or “pins” is attached to the substrate. An example of the use of a multi-layer substrate to increase I/O is shown in U.S. Pat. No. 5,530,287 to Currie.

A problem with modem multi-layer chip substrate packages is that the connection path between the chip and the edge of the lead frame may be unnecessarily long. Often to make the necessary electrical connection, the traces must be configured to pass back and forth on subsequent levels to avoid crossing or being blocked by other traces before being connected to the output pad. Also, the traces are in close proximity to one another, while simultaneously running electrical currents. This leads to crosstalk and a loss of bandwidth. Designers can attempt to reduce such problems by separating the circuit traces through the substrate, but this only extends the circuit path length, leading to the need for higher power input and reducing interconnection speed. Yet further problems are that as a result of their inherent complexity and the need for automated production equipment, multi-layer substrates are costly to design and fabricate, and require considerable planning and lead time before they can go into production.

On the upper surface of the substrate wire bonding is commonly used to provide electrical connections between the semiconductor chips and the terminal pads on the substrate, and also directly between the chips themselves. The currents carried by adjacent wires frequently interact, creating extraneous capacitance and inductance which has the undesirable effect of increasing crosstalk and reducing bandwidth. This effect is particularly acute with respect to the wire bonds connecting chips to terminal pads on the substrate. Typically, adjacent wires are positioned parallel to one another to avoid contact and potential short circuiting. However, parallel wires have electrical fields which reinforce one another, which exacerbates the undesirable inductance and capacitance effects.

### SUMMARY OF THE INVENTION

What is desired is a high density integrated circuit package which overcomes one or more of the problems associated with the current devices and methods used for integrating chips into integrated circuit packages.

It is a principal object of the present invention to provide a method of microelectronic circuit packaging in which a plurality of bond pads may be formed on the entire surface of the microchip in an area array configuration rather than just around its perimeter.

It is another object of the present invention to provide wire bonding of connection wires to the area array configured bond pads of the microchip with insulated wire.

It is another object of the present invention to provide microelectronic circuit packaging with ultra fine pitch between adjacent wires without potential short circuit problems.

It is another object of the present invention to provide microelectronic circuit packaging with extremely reliable mating between the bonding wires and the bond pads.

It is yet another object of the present invention to provide microelectronic circuit packaging in which Multichip modules (MCMs) may be produced using direct chip-to-chip connections.

It is still yet another object of the present invention to provide microelectronic circuit packaging which is simple, inexpensive, reliable, and may be produced quickly to meet the demands of the industry.

The method comprises of forming a plurality of aluminum metallized bonding pads at a plurality of locations accessing the entire surface area of the microchip, and insulated aluminum alloy wires are ball bonded to the bonding pads of the microchip and the terminal pads of the connecting substrate forming the microelectronic device.

The integrated circuit package should preferably enable a semiconductor chip to be packaged with a substrate that has a minimal number of layers, and preferably only a single layer. The package preferably would also be leadless, i.e. with no lead frames, to minimize costs and package size. Since there would be fewer substrate layers to design and manufacture, production costs and lead time would be reduced and rapid prototyping would become easier. Such an arrangement would also have the benefit of reducing interlayer capacitance and inductance, which would increase bandwidth performance and reduce crosstalk. Finally, it would be preferable for the integrated circuit package to reduce the degree of parallelism between adjacent bond wires, to reduce cross-wire inductance and capacitance and further reduce crosstalk while increasing bandwidth, without increasing circuit path length.

Accordingly, there is provided a high density integrated circuit package comprising:

a) a substrate having terminal pads arranged in at least one row along a perimeter of a surface of said substrate;

b) vias connecting said terminal pads directly to connectors on an opposite side of said substrate;

c) a semiconductor chip mounted on the substrate, inside said perimeter, said chip having bond pads located on a surface of said chip; and

d) a plurality of insulated bond wires, each of said bond wires extending from a bond pad on said chip to a terminal pad on said substrate, said substrate being sized and shaped to provide a sufficient number of rows of terminal pads and associated vias so that horizontal traces through said substrate are not required.

### BRIEF DESCRIPTION OF THE DRAWINGS

Reference will now be made, by way of example only, to preferred embodiments of the invention as illustrated in the attached figures.

FIG. 1 is a schematic elevation diagram showing the bonding pads provided around the perimeter of a microchip in prior art microelectronic circuit devices.

FIG. 2 is a schematic elevation diagram showing the bonding pads provided in two staggered rows around the perimeter of prior art microelectronic circuit devices.

FIG. 3 is a schematic elevation diagram showing the full array of a plurality of bonding pads formed over the entire surface of the microchip according to the present invention.

FIG. 4 is a schematic elevation diagram showing the interstitially depopulated array of a plurality of bonding pads formed over the entire surface of the microchip according to the present invention.

FIG. 5 is a schematic elevation diagram showing the random array of a plurality of bonding pads formed at selected locations over the entire surface of the microchip according to the present invention.

FIG. 6 is an isolated and enlarged partial section elevation side view showing an insulated aluminum wire ball bonded to a bonding pad of a microchip disposed on a substrate.

FIG. 7 is an isolated top elevation partial view showing the random placement of bond wires connected to bonding pads of a microchip according to the present invention.

FIG. 8 is a perspective elevation view of a Multichip module (MCM) having a plurality of microchips using direct chip-to-chip wire connections according to the present invention.

FIG. 9 is a top view of the integrated circuit package of the present invention;

FIG. 10 is a side view of the integrated circuit package of the present invention;

FIG. 11a is a top view of the integrated circuit package of the present invention, showing the bond wires in a staggered X-Y grid pattern;

FIG. 11b is a top view of the integrated circuit package of the present invention, showing the bond wires in an in-line X-Y grid pattern;

FIG. 12 is a schematic top view of the integrated circuit package of the present invention, showing a layout of a substrate having terminal pads and vias suitable for prototyping.

### DETAILED DESCRIPTION OF THE PREFERRED EMBODIMENTS

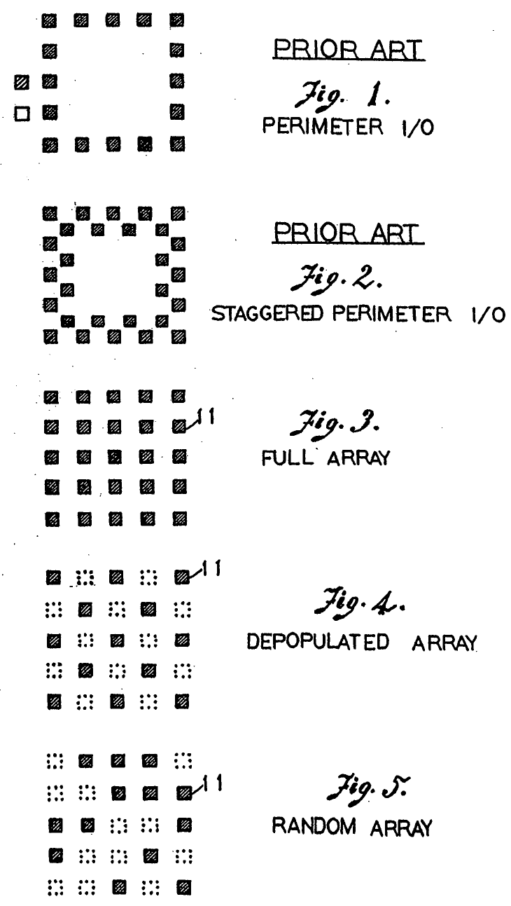

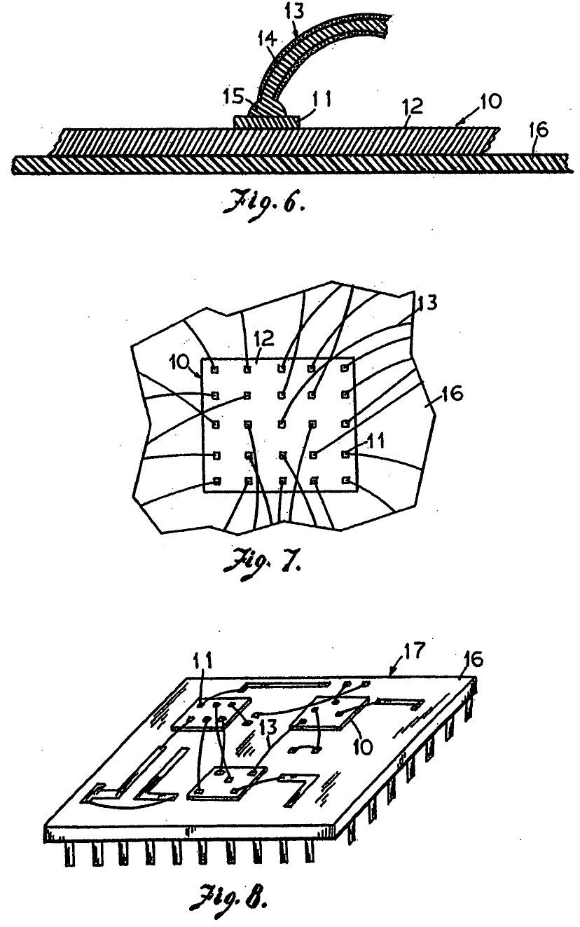

With reference to the drawings wherein like reference numerals designate corresponding parts in the several views, a microchip 10 having a full area array of a plurality of bond or bonding pads 11 formed thereon is best shown in the schematic diagram in FIG. 3. The bonding pads 11 are comprised of metallized aluminum. With the full utilization of the entire surface area of the microchip surface 12 typically from 900 to 10000 I/O connections may be made on a single microchip having a die size (i.e. width of chip) of 3 to 10 mm (120 to 400 mils) respectively given a bond pitch of 4 mils (100 microns). Such a high density of I/O interconnections are many times more than the modest provisions offered by conventional wire bond connection methodology which adopts a single rowed or staggered rowed bonding pattern around the perimeter of the microchip as presently shown in the schematic diagrams in FIGS. 1 and 2. For simplicity of illustration, five columns and five rows of bond pads are shown on the entire surface 12 of the microchip 10 in FIG. 7. Such extremely high number of I/O connections have not been achieved by wire bonding onto bond pads arranged around the perimeter of the microchip. Furthermore, an interstitially depopulated array of bond pad pattern or matrix as best shown in FIG. 4, or a randomly depopulated array of bond pad pattern or matrix as best shown in FIG. 5 may be provided. The randomly depopulated array is particularly advantageous for use with a microchip which may have faulty areas that are not usable. Also, it simplifies the selection of locations for forming the bond pads. Alternatively, unused areas may be reserved for potential future repair or rework of the microelectronic circuit package. Such flexibility and provision cannot be achieved with microchips having I/O areas provided only around their perimeter.

Pre-insulated bond wire 13 having an insulated outside coating 14 is used to form ball bond 15 with bond pad 11. Pre-insulated gold bond wire of 1 mil diameter having a dielectric thickness of less than 1 micron is preferred. Gold wire having an outer insulated coating such as that shown in U.S. Pat. No. 5,396,104 to Masao Kimura may also be used. Furthermore, since the bond wires 13 are insulated, it alleviates the problem of short circuiting due to their contacting one another which is not permissible in prior art devices using bare bond wires. As the bond wires are insulated, the placement and looping of such wires are not as critical in the packaging process, making the process less complex and thus it may be carried out at a much faster speed.

Aluminum wires 13 are connected to terminal pads on the substrate 16 in the conventional manner so as to form the final IC. A protective epoxy coating may be applied to the IC. Since the bond wires 13 are insulated, no potential short circuiting among the bond wires may occur even if the bond wires change their positions to contact one another due to “wire sweep”. For the above reasons, the IC packaging according to the present invention may be carried out to meet the industry's demand for “cheaper, faster, and denser” microchips.

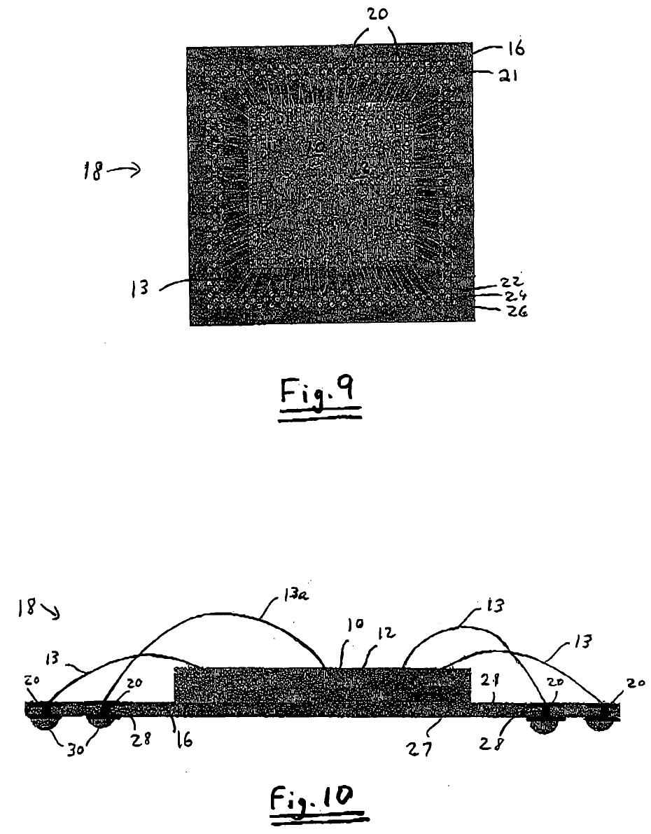

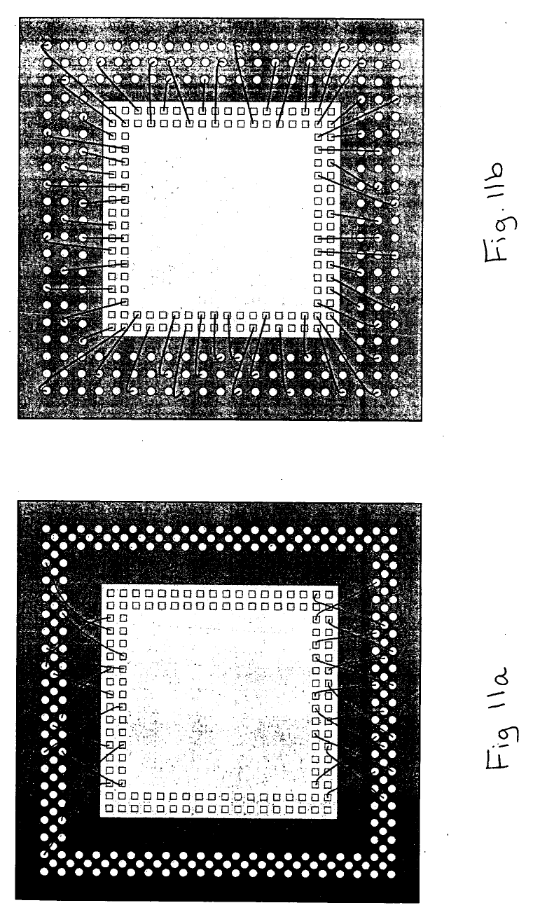

A Multichip module 17 as shown in FIG. 8 may be formed with the present invention by making use of the insulated wire to produce direct chip-to-chip connections among a plurality of microchips 10 disposed on a single layer substrate 16. The capability of making direct chip-to-chip connections eliminates the critical drawback of conventional methods in using composite multilayered substrates for making MCMs in which connections among the microchips are attached and connected to a high density multilayered substrates with a relatively dense network of fine connection or trace lines provided in the various substrate layers as shown in U.S. Pat. No. 5,373,188 to Kazumari Michii et al. Such a composite multilayered substrate is complex and costly to produce whereas a simple single layer substrate is all that is required for producing the MCM of the present invention. Furthermore, the routing of the trace lines in the high density substrate construction is inflexible due to the density of the lines that must be provided on the limited space available in each layer. With the direct chip-to-chip connections of the present invention, not only is the significant cost for a high density substrate eliminated, the interconnection cost may be halved, since a direct chip-to-chip connection with the insulated wire may be achieved with only one wire bond whereas the indirect connections between chips using the trace lines in the multilayered substrate require two wire bonds as shown also on U.S. Pat. No. 5,373,188 to Kazumari Michii et al.

Furthermore, the present invention addresses a problem in the IC industry of the “pad limited” die (the number of bonding pads determines the die size not the circuitry) due to the peripheral bonding of high I/O devices. The present invention assists in producing chips dramatically reduced in size that have the same I/O performance of much larger peripherally bonded chips. Thus, it permits die shrink. The advantage of die shrink or smaller die is that more physically smaller microchips may be formed outside of the defective region of a semiconductor wafer, therefore, it increases the yield of the production of the microchip to result in dramatic cost savings and higher production yields.

Another view of the integrated circuit package or device of the present invention is shown in a top view in FIG. 9. The package is generally indicated with reference numeral 18, and broadly comprises the substrate 16 and at least one semiconductor chip 10. The substrate has terminal pads 20 arranged in at least one row along a perimeter of the substrate upper surface 21. The chip 10 is shown mounted on the substrate 16, inside the perimeter of the substrate 16 as defined by the terminal pads 20. The chip 10 has upper surface 12 and bond pads 11 arranged on this surface. The bond pads 11 can be located anywhere on the upper surface 12, but are shown in FIG. 9 forming two rows arranged along an outer perimeter. FIG. 9 also shows the plurality of insulated bond wires 13, each of which extends from a bond pad 11 on the chip 10 to a terminal pad 20 on the substrate 16. Specifically, each of the bond wires have two ends, one of which attaches, or forms a fixed electrical connection to one of the bond pads 11 and the terminal pads 20 respectively.

The elements of the present invention 18 are used in a wide variety of electronic devices. The chip 10 is most generally manufactured from a larger silicon wafer, and contains an electronic circuit in the form of a pattern of components and connections that provide one or more electronic functions. The particular placement of the bond pads 11 correspond to locations on the chip 10 where it may be desired to access the electronic signal at that point. Such access is often for the purpose of input/output functions with other chips or devices. The signals available at the bond pads are carried by the bond wires to the terminal pads, where as will be shown further contact points are provided to connect with the broader circuit.

The substrate 16 is most likely made from a non-conductive plastic material. The bond pads and terminal pads may be made from any conductive material or metal, but are preferably aluminium. These pads are preferably square, about 2 mils (50 microns) on each side. The bond wires may be made from any conductive material or metal, but are preferably gold, aluminium, or copper, most preferably gold. The wires may be bare conductive bond wires separated by an air gap or electrically insulating material, but preferably are pre-insulated bonding wires. The bond wire is usually provided on a spool. Bonding is achieved by positioning a free end on or about the target pad and providing focused energy such as an electrical discharge to form a bond ball which is pressed to form a durable bond.

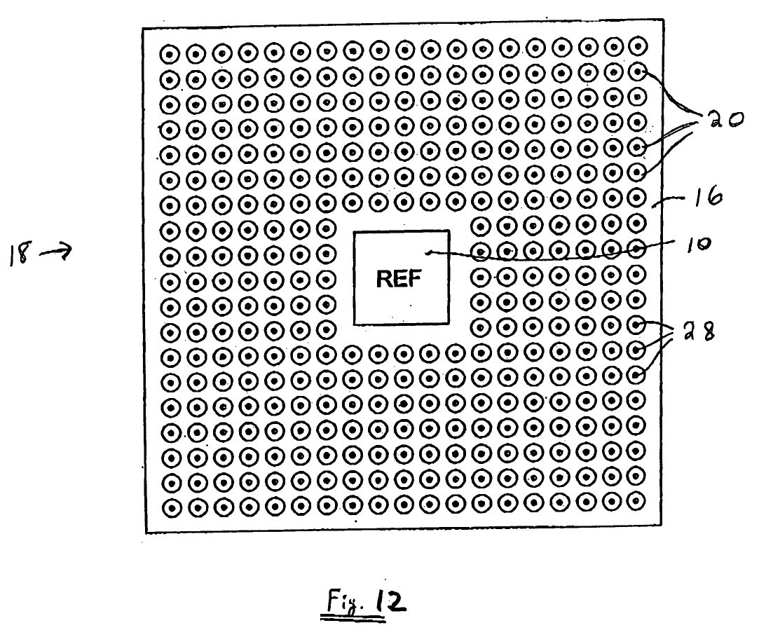

The perimeter of the substrate 16 where the terminal pads 20 are located comprehends any part of the surface that is not otherwise occupied by the chip 10. For further reference FIG. 12 shows a representation of a package 18 in which the chip 10 is relatively small compared to the substrate 16. It can be seen that there are many terminal pads 20, all of which are considered to be on the perimeter of the substrate 16. Preferably the chip 10 is mounted at or about a center of the substrate 16, as shown in FIG. 9. This is preferable because the terminal pads may then be laid in rows that are conveniently parallel and symmetric, and will further be equidistant from the bond pads, which simplifies wire bonding and production of the package. However it can be appreciated that if the chip 10 were placed on an edge of the substrate 16, the perimeter would then comprehend that part of the substrate 16 that borders the three open sides of the chip 10.

In the present invention, the substrate 16 is sized and shaped to provide a sufficient number of rows of terminal pads 20 so that at least one dedicated terminal pad 20 is available to receive each of the insulated bond wires 13 extending from the bond pads 11. In FIG. 9, it can be seen that there are three rows of terminal pads 16, numbered 22, 24, and 26, respectively. This provides sufficient number of terminal pads 20 so that a terminal pad is available to receive a bond wire 13 from each of the bond pads 11 on chip 10. In FIG. 9 it can be seen that the bond pads 11 are arranged along two rows around an outer perimeter of upper surface 12 of the chip 10. It can be appreciated that if more bond pads 11 had been provided, for example, three, four, or more rows to fill in the surface 12, additional rows of terminal pads 20 would need to be provided on the surface 21 of substrate 16. It can be further appreciated that the size of substrate 16 is also a function of the size of the chip 10, as well as the number of bond pads 11 on the chip. In FIG. 9, for example, chip 10 is relatively substantial in comparison to substrate 16, so that if the chip were completely filled with bond pads 11 it might become necessary to select a larger substrate 16, to accommodate sufficient rows of terminal pads 20.

It can now be appreciated how in the present invention the substrate 16 provides as many rows of terminal pads as required to accommodate the bond pads 11. It can further be appreciated that, since the bond pads 11 can be placed anywhere on the surface of the chip 10, and since the bond pads are relatively small, at about 2 square mils, compared to the chip 10, which is commonly in the range of 100-400 square mils, that the number of bond pads 11 to be connected may be fairly large, for example in the range of 1,000 to 10,000 bond pads. The present invention can accommodate as many bond pads as provided by arranging the terminal pads in rows and providing an appropriately sized substrate 16 so that there are a sufficient number of terminal pads to receive bond wires from the bond pads.

A side view of the integrated circuit package 18 is shown in FIG. 10. The chip 10 can be seen mounted on the substrate 16, with bond wires 13 connecting bond pads on the upper surface 12 of chip 10 to terminal pads 20 on the upper surface 21 of the substrate 16. In this view it can be seen that electrically conductive vias or via holes 28 directly connect the terminal pads 20 to connectors such as ball connectors 30 located on an opposite side of substrate 16. In FIG. 10 the opposite side of substrate 16 is shown as an underside or bottom surface 27 of the substrate, and the connector configuration on bottom surface 27 is a ball grid array.

It can be appreciated that since each bond pad 11 is connected to an individual terminal pad 20, each bond pad 11 is similarly connected through a via 28 to an individual ball connector 30. Therefore, every point on the chip 10 which provides an electrical signal that it is desired to access, and is accessible through a bond pad 11, is available at a ball connector 30. In turn, these signals will become conveniently available to the overall circuit when the package 18 is fitted into place using the standard couplings available for ball grid arrays.

It can further be appreciated that since the present invention provides a terminal pad and ball connector for each bond pad, there is a reduced need for a multi-layer substrate and its associated connectivity elements such as lateral circuit traces and interlayer via holes. In particular, the substrate 16 can be a minimal layer substrate, and most preferably is a single layer substrate as shown in FIG. 10. Preferably, there are no lateral circuit traces or lead frames, and the via holes directly traverse the substrate 16, as shown in FIG. 10.

It can be appreciated therefore that in the present invention, the substrate 16 is sized and shaped to provide a sufficient number of rows of terminal pads and associated vias so that horizontal or lateral circuit traces through the substrate are not required. Further, the configuration of the present invention reduces interlayer inductance and capacitance because first, there are minimal layers or only a single layer, and second, there are substantially no lateral circuit traces. In turn, this leads to a reduction in crosstalk and an increase in the range of bandwidth performance.

In the past it has been necessary, when bonding from bond pads to terminal pads, to align the bond wires so that adjacent wires were parallel. This was necessary to prevent any uninsulated wires from crossing, which could lead in turn to shorting between bond wires. However, the parallel configuration reinforced the inductance and capacitance effects, and gave rise to increased cross-talk and a reduction in bandwidth. In the present invention, insulated wire 13 is used. Therefore, it is not necessary to maintain a parallel alignment of bond wires 13, since the insulation will prevent shorting between crossed wires. Further, in the present invention it is preferable to position the wires 13 to reduce parallelism between adjacent wires, for example, by positioning the wires so that they cross one another. This may be accomplished, for example, by positioning the insulated bond wires in a generally X or Y shaped pattern. FIGS. 11a and 11b illustrate in-line and staggered X or Y grid patterns, respectively. It can be appreciated that by crossing bond wires to reduce parallelism, the amount of inductance and capacitance above the surface of the substrate is reduced, leading to a reduction in cross-talk and an increase in the range of bandwidth performance.

The present invention facilitates delivery of electrical power and ground to circuit connection points located in the interior or core of the microchip. Interior or core means the center of the surface of the microchip, and in addition means a portion of the surface area emanating from the center up to the point along the perimeter or edge of the chip which could be occupied by the bond pads of the prior art.

When bond pads are only available on the perimeter of the microchip, such connections have to be routed from the chip interior to the perimeter bonding pads using the internal conductors of the chip. The internal conductors are generally thin or fine, and are therefore limited in the size of current they can carry. Chips having interior power or ground connections may consequently have to operate at a lower power level, which could impede performance. In addition, the power or ground connection usually proceeds from the bond pad to a terminal pad by bond wire, and then possibly for some distance within a multi-layer substrate. The distance and complexity of the path through the substrate may also impose limitations on the current available for delivery to the chip.

It can be appreciated that the present invention enables the power or ground connection to be made to a bond pad placed in the interior of the chip, right at the point where it is needed. An insulated bond wire can be directly connected between the bond pad and a terminal pad on the substrate. In this way, routing through the fine internal conductors of the chip is avoided, and the previous current and power limitations are no longer a factor. Preferably the substrate is a minimal or single layer substrate, with a single via hole providing a direct connection to a lead electrically connected to the source of power or ground. In FIG. 10, bond wire 13a is shown connecting a point in the interior or core of semiconductor chip 10 to the ball connector 30.

The method by which the integrated circuit package of the present invention is produced can now be described. The designer commences by selecting an integrated circuit chip to fulfill the desired electronic function. The chip has bond pads located anywhere on its surface. At least a portion of the bond pads correspond to electrical signals within the chip that are to be integrated into the overall circuit, generally by connecting to other chips in the same package, or to other chips or devices outside the package. These bond pads may also be characterized as being designated to provide input/output functions.

The next step involves providing a substrate 16 having terminal pads 20 arranged in at least one row along a perimeter of a first or upper surface 21, of the substrate. The substrate can have vias or via holes directly connecting each of the terminal pads on the upper surface 21 to connectors on an opposite side of the substrate, such as to ball connectors 30 comprising a ball grid array on the lower surface 27. The substrate would be sized and shaped to contain a sufficient number of rows of terminal pads and associated vias so that at least one dedicated terminal pad is available for each of the bond pads designated to provide input/output functions, and so that horizontal or lateral traces through the substrate are not required. The substrate would also preferably be leadless, and contain a ball grid array or similar connector configuration.

The chip or chips are then mounted on the upper surface 21 of the substrate, inside the perimeter. The insulated bond wires 13 are connected between the bond pads 11 and the terminal pads 20. Preferably, these bond wires are positioned to reduce parallelism between adjacent wires, to in turn reduce cross talk and increase the range of bandwidth performance.

It can be appreciated that the above method of production enables integrated circuit packages to be rapidly developed. Since a single layer substrate is adequate, the time and cost involved in designing a complex multi-layer substrate having complicated lateral circuit traces, and then fabricating such a device, is eliminated. This rapid development, also known as “quick turn packaging”, provides benefits in improved efficiency in manufacturing. Further, it also reduces the distinction between prototyping and production, since both prototype and finished product will in most cases share a common, single layer substrate. New configurations therefore can be more quickly and easily built, tested, and modified, before moving to production.

The present invention lends itself to the use of a standardized substrate, such as shown in FIG. 12. In this figure a central space is left available for a prototype chip to be tested, and all the remaining space is occupied with terminal pads 20 having via holes 28. Such a substrate would in most cases have more than enough terminal pads to accommodate the active bond pads on the prototype chip.

It will be appreciated by those skilled in the art that the foregoing description was in respect of preferred embodiments and that various alterations and modifications are possible within the broad scope of the appended claims without departing from the spirit of the invention. For example, while reference is made to the substrate using ball grid arrays, other types of substrate connectors are comprehended. Various other modifications will be apparent to those skilled in the art but are not described in any further detail herein.

The embodiments of the invention in which an exclusive property or privilege is claimed are defined as follows:

1. A method of packaging a high-density integrated circuit with at least one microchip disposed on a substrate comprising:
(a) providing pre-insulated bond wires;
(b) forming an array of coated bonding pads on said microchip; and
(c) attaching said pre-insulated bond wires directly onto said bonding pads and directly onto terminal pads disposed on said substrate.

2. The method of packaging a high density integrated circuit according to claim 1, wherein said bonding pads are located at selected locations on said microchip.

3. The method of packaging a high density integrated circuit according to claim 2, wherein said bonding pads comprise a metallized aluminium, gold, or copper material.

4. The method of packaging a high density integrated circuit according to claim 1, wherein said pre-insulated bond wires are selected from a group consisting of gold, aluminum, copper and combinations thereof.

5. The method of packaging a high density integrated circuit according to claim 1, wherein said pre-insulated bond wires are attached onto said bonding pads by a ball shaped joint.

6. The method of packaging a high density integrated circuit according to claim 1, wherein a plurality of microchips are disposed on said substrate and said bonding pads are located on the microchips.

7. The method of packaging a high density integrated circuit according to claim 6, including attaching said pre-insulated bond wires to said bonding pads to thereby connect adjacent microchips.

8. A method of packaging a high density integrated circuit having at least one semiconductor microchip disposed on a substrate having a plurality of terminal pads provided thereon, comprising;
(a) providing pre-insulated bond wires;
(b) forming a plurality of bonding pads in a plurality of rows and columns over a surface of said microchip; and
(c) connecting selected bonding pads on said microchip with selected terminal pads on said substrate with said pre-insulated bond wires.

9. The method of packaging a high density integrated circuit according to claim 8, including coating the integrated circuit with a protective encapsulating material.

10. The method of packaging a high density integrated circuit according to claim 8, wherein said bonding pads are located at selected locations over the entire surface of said microchip.

11. The method of packaging a high density integrated circuit according to claim 8, wherein a plurality of semiconductor microchips are disposed on said substrate, and interconnections among selected bonding pads on said microchips are provided by pre-insulated bond wires bonded to said selected bonding pads.

12. The method of packaging a high density integrated circuit according to claim 11, wherein said pre-insulated bond wires are selected from a group consisting of gold, aluminium, copper and combinations thereof.

13. An integrated circuit package comprising:
(a) a substrate having terminal pads arranged in at least one row along a perimeter of a surface of said substrate;
(b) vias connecting said terminal pads directly to connectors on an opposite side of said substrate;
(c) a semiconductor chip mounted on the substrate, inside said perimeter, said chip having bond pads located on a surface of said chip; and
(d) a plurality of insulated bond wires, each of said bond wires extending from a bond pad on said chip to a terminal pad on said substrate, said substrate being sized and shaped to provide a sufficient number of rows of terminal pads and associated vias so that horizontal traces through said substrate are not required.

14. An integrated circuit package as claimed in claim 13, wherein said substrate is configured to contain a minimal number of layers, to reduce interlayer inductance, capacitance, and cross talk, and to increase the range of bandwidth performance.

15. An integrated circuit package as claimed in claim 14, wherein said substrate is a single layer substrate.

16. An integrated circuit package as claimed in claim 14, wherein said substrate contains no lead frames.

17. An integrated circuit package as claimed in claim 16, wherein said opposite side of said substrate contains a ball grid array, and each of said terminal pads connects to a ball in said ball grid array through said via directly traversing said substrate.

18. An integrated circuit package as claimed in claim 13, wherein said insulated bond wires extending between said bond pads on said chip and said terminal pads on said substrate are positioned to reduce parallelism between adjacent wires, to in turn reduce cross talk and increase the range of bandwidth performance.

19. An integrated circuit package as claimed in claim 18, wherein said insulated bond wires are attached in a generally X or Y shaped pattern.

20. An integrated circuit package as claimed in claim 19, wherein said generally X or Y shaped pattern is an in line or staggered X-Y grid pattern.

21. An integrated circuit package as claimed in claim 13, wherein at least one of said bond pads is located in an interior portion of said surface of said chip.

22. An integrated circuit package as claimed in claim 21, wherein said bond pad located in said interior portion is electrically connected to one of a power connection and a ground connection on said chip.

23. A method of manufacturing an integrated circuit package, said method comprising:
(a) providing a semiconductor chip having bond pads located on a surface of said chip, at least a portion of said bond pads being designated to provide input/output functions;
(b) providing a substrate having terminal pads arranged in at least one row along a perimeter of a surface of said substrate, said substrate having vias connecting said terminal pads directly to connectors on an opposite side of said substrate, said substrate being sized and shaped to contain a sufficient number of rows of terminal pads and associated vias so that horizontal traces through said substrate are not required;
(c) mounting said semiconductor chip on said surface of said substrate, inside said perimeter; and
(d) connecting insulated bond wires between said portion of said bond pads and said terminal pads.

24. A method of manufacturing as claimed in claim 23, wherein said step of connecting insulated bond wires in step (d) comprises positioning said bond wires to reduce parallelism between adjacent wires, to in turn reduce cross talk and increase the range of bandwidth performance.

25. A method of manufacturing as claimed in claim 23, wherein said connectors on said opposite side of said substrate are balls in a ball grid array.
